(19) United States
(12) Patent Application Publication
(10) Pub. No.: US 2022/0157681 A1
(43) Pub. Date: May 19, 2022

(54) INTEGRATED CIRCUIT PACKAGE WITH V-SHAPED NOTCH CREEPAGE STRUCTURE

(71) Applicant: STMicroelectronics SDN BHD, Muar (MY)

(72) Inventor: Yang Hong HENG, Muar (MY)

(73) Assignee: STMicroelectronics SDN BHD, Muar (MY)

(21) Appl. No.: 17/494,298

(22) Filed: Oct. 5, 2021

Related U.S. Application Data
(60) Provisional application No. 63/114,602, filed on Nov. 17, 2020.

(51) Int. Cl. H01L 23/31; H01L 23/495

(52) U.S. Cl. CPC H01L 23/3121; H01L 25/18; H01L 23/49575; H01L 23/49555

(57) ABSTRACT

A lead frame includes a die pad and electrical leads. An integrated circuit chip is mounted to the die pad. An encapsulating package has a perimeter defined by first, second, third and fourth sidewalls. The electrical leads extend from the opposed first and second sidewalls of the package. At least one sidewall of the opposed third and fourth sidewalls of the package includes a V-shaped concavity functioning to increase a creepage distance between the electrical leads at the opposed first and second sidewalls.

### CROSS REFERENCE TO RELATED APPLICATIONS

This application claims priority from U.S. Provisional Application for Patent No. 63/114,602, filed Nov. 17, 2020, the disclosure of which is incorporated herein by reference.

### TECHNICAL FIELD

The present invention generally relates to integrated circuit devices and, in particular, to a package for an integrated circuit device that includes a V-shaped notch creepage structure formed in a peripheral package sidewall between external electrical terminals to ensure a sufficient creepage distance between those external electrical terminals.

### BACKGROUND

Reference is made to FIGS. 1 and 2. A power integrated circuit device 10 typically includes a first integrated circuit chip 12 which provides a power element (or function) and a second integrated circuit chip 14 which provides a control element (or function). The lead frame 16 for the power integrated circuit device 10 includes a first die pad 18 to which the first integrated circuit chip 12 is mounted and a second die pad 20 to which the second integrated circuit chip 14 is mounted. A first set of leads 22a-22n extend away from the first die pad 18 and a second set of leads 24a-24p extend away from the second die pad 20. A first set of pads of the first integrated circuit chip 12 are electrically connected to the proximal ends of the first set of leads 22a-22n by bonding wires 26, and a first set of pads of the second integrated circuit chip 14 are electrically connected to the proximal ends of the second set of leads 24a-24p by bonding wires 26. A second set of pads of the first integrated circuit chip 12 are electrically connected to a second set of pads of the second integrated circuit chip 14 by bonding wires 26. A package 30 typically made of a resin material encapsulates the first and second integrated circuit chips 12 and 14, the lead frame 16 and the bonding wires 26. The package 30 has in top view a square or rectangular shaped perimeter defined by peripheral package sidewalls 32. In the illustrated embodiment, distal ends of the leads 22 and 24 extend out from opposite peripheral package sidewalls 32a and 32b. Opposite peripheral package sidewalls 32c and 32d extend perpendicular to and respectively join the opposite peripheral package sidewalls 32a and 32b.

As power integrated circuit devices 10 continue to become smaller in size, especially in terms of occupied area, the distance between the distal ends of ones of the first set of leads 22a-22n and the ends of ones of the second set of leads 24a-24p becomes shorter. This increases the risk that an electrical arc can form along the one of the opposite sides 32c and 32d of the peripheral package sidewall (for example, between lead 22n and lead 24a) because the creepage distance CD has been shortened. There is a need in the art to address this concern.

### SUMMARY

In an embodiment, an integrated circuit device comprises: a package that encapsulates a lead frame and at least one integrated circuit chip, wherein the at least one integrated circuit chip is mounted to a die pad of the lead frame, said lead frame further including a plurality of leads; wherein the package has, in top view, a square or rectangular perimeter defined by first, second, third and fourth sidewalls; wherein first and second sidewalls are opposite each other; wherein third and fourth sidewalls are opposite each other; wherein a first set of the plurality of leads extend along the first sidewall and a second set of the plurality of leads extend along the second sidewall; and wherein at least one of the third and fourth sidewalls includes a V-shaped concavity.

In an embodiment, an integrated circuit device comprises: a package that encapsulates a lead frame, a first integrated circuit chip and a second integrated circuit chip, wherein the first integrated circuit chip is mounted to a first die pad of the lead frame and electrically connected to a first plurality of leads of the lead frame, wherein the second integrated circuit chip is mounted to a second die pad of the lead frame and electrically connected to a second plurality of leads of the lead frame; wherein the package has, in top view, a square or rectangular perimeter defined by first, second, third and fourth sidewalls; wherein first and second sidewalls are opposite each other; wherein third and fourth sidewalls are opposite each other; wherein the first plurality of leads extend along the first sidewall and the second plurality of leads extend along the second sidewall; and wherein at least one of the third and fourth sidewalls includes a V-shaped concavity.

### BRIEF DESCRIPTION OF THE DRAWINGS

For a better understanding of the embodiments, reference will now be made by way of example only to the accompanying figures in which:

FIG. 1 is a schematic top view and FIG. 2 is a perspective view, respectively, of a power integrated circuit device; and

FIG. 3 is a schematic top view and FIG. 4 is a perspective view, respectively, of a power integrated circuit device that includes a V-shaped notch creepage structure formed in a peripheral package sidewall.

### DETAILED DESCRIPTION

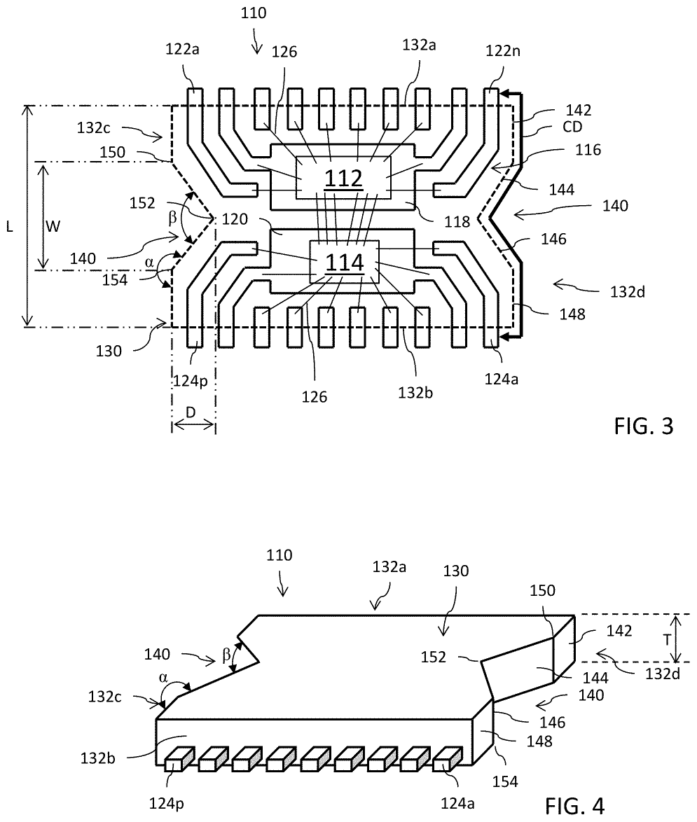

Reference is made to FIGS. 3 and 4. A power integrated circuit device 110 includes a first integrated circuit chip 112 which provides a power element (function) and a second integrated circuit chip 114 which provides a control element (function). The lead frame 116 for the power integrated circuit device 110 includes a first die pad 118 to which the first integrated circuit chip 112 is mounted and a second die pad 120 to which the second integrated circuit chip 114 is mounted. A first set of leads 122a-122n extend away from the first die pad 118 and a second set of leads 124a-124p extend away from the second die pad 120. A first set of pads of the first integrated circuit chip 112 are electrically connected to the proximal ends of the first set of leads 122a-122n by bonding wires 126, and a first set of pads of the second integrated circuit chip 114 are electrically connected to the proximal ends of the second set of leads 124a-124p by bonding wires 126. A second set of pads of the first integrated circuit chip 112 are electrically connected to a second set of pads of the second integrated circuit chip 114 by bonding wires 126.

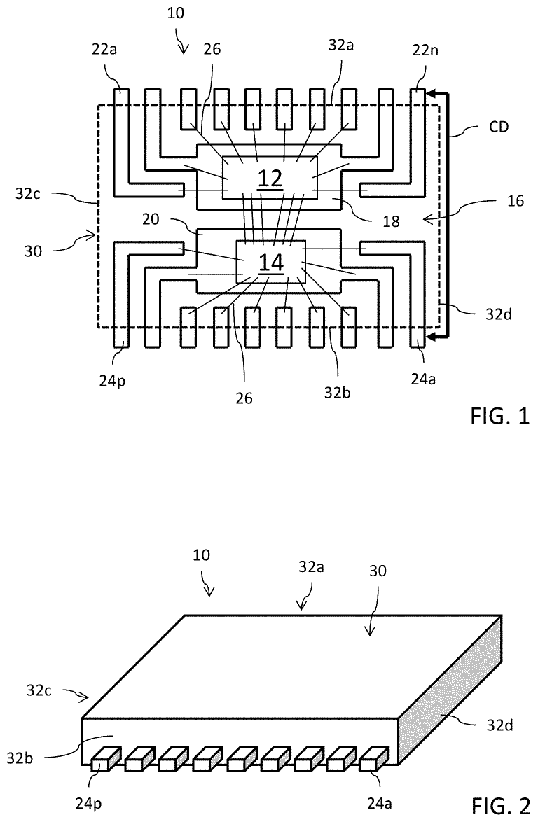

A package 130 typically made of a resin material encapsulates the first and second integrated circuit chips 112 and 114, the lead frame 116 and the bonding wires 126. The package 130 has in top view a square or rectangular shaped perimeter defined by peripheral package sidewalls 132. In the illustrated embodiment, distal ends of the leads 122 and 124 extend out from opposite peripheral package sidewalls 132a and 132b. Opposite peripheral package sidewalls 132c and 132d respectively join the opposite peripheral package sidewalls 132a and 132b. The opposite peripheral package sidewalls 132c and 132d differ from the opposite peripheral package sidewalls 32c and 32d of FIGS. 1 and 2 in that each peripheral package sidewall 132c and 132d includes a V-shaped concavity 140 provided across an entire thickness T between top and bottom surfaces of the package 130. Each of the peripheral package sidewalls 132c and 132d is defined by a first sidewall portion 142, a second sidewall portion 144 joined to the first sidewall portion 142 at an outside corner 150, a third sidewall portion 146 joined to the second sidewall portion 144 at an inside corner 152, and a fourth sidewall portion 148 joined to the third sidewall portion 146 at an outside corner 154. The outside corner 150 is defined by an outside angle α between the first sidewall portion 142 and the second sidewall portion 144. The inside corner 152 is defined by an inside angle β between the second sidewall portion 144 and the third sidewall portion 146. The outside corner 154 is defined by an outside angle α between the third sidewall portion 146 and the fourth sidewall portion 148. The first sidewall portion 142 extends perpendicularly from the peripheral package sidewall 132a, and the fourth sidewall portion 148 extends perpendicularly from the peripheral package sidewall 132b.

The presence of the V-shaped concavity 140 in each of the peripheral package sidewalls 132c and 132d provides for a creepage distance CD that is longer than is present in the embodiment shown in FIGS. 1 and 2. The second integrated circuit chip 114 which provides a control element may be exposed to a relatively lower voltage (for example, less than or equal to 24V) while the first integrated circuit chip 112 which provides a power element may be exposed to a relatively higher voltage (for example, approximately 4,000V). A minimum creepage distance at the outer surface of the package 130 is required to have sufficient electrical insulation between the two integrated circuit chips (in particular, between one of the leads 122 for the first integrated circuit chip 112 and one of the leads 124 for the second integrated circuit chip 114). With use of the V-shaped concavity 140 in the peripheral package sidewalls 132c and 132d, the package 130 may occupy a smaller area while still satisfying the minimum creepage distance requirement.

Provision of the 130 with V-shaped concavities 140 on opposite peripheral package sidewall 132c and 132d is accomplished through the use of well-known transfer molding technology, but where the mold cavity is formed to define the concavity. Additionally, the lead frame 116 is designed in a way that the leads 122 or 124 are routed to not extend into the area where the V-shaped concavity 140 will be present. This is accomplished, for example, by forming or shaping outer leads extending from the die pads 118 and 120 with a bend to avoid the area of the V-shaped concavity 140.

In a preferred implementation, the V-shaped concavity 140 formed by the second sidewall portion 144 and third sidewall portion 146 has a width W defined between the outside corners 150 and 154 that is between 0.35*L and 0.55*L, where L is a length of the peripheral package sidewall 132c, 132d. The width W is set, at least in part, by the choice of the angles α and/or β.

In a preferred implementation, the V-shaped concavity 140 formed by the second sidewall portion 144 and third sidewall portion 146 has a depth D from the plane defined by the first sidewall portion 142 and fourth sidewall portion 148 to the corner 152 that is between 0.15*L and 0.30*L. The depth D is set, at least in part, by the choice of the angles α and/or β.

In a preferred implementation, the inside corner 152 for the V-shaped concavity 140 is positioned substantially midway between the opposite peripheral package sidewalls 132a and 132b. However, this is not a requirement and positioning of the V-shaped concavity 140 is typically driven by the relative shape and configuration of the lead frame 116. The example lead frame 116 shown in FIG. 3 is symmetric and generally mirror imaged, but this is not a requirement. In the case of an asymmetric shape and configuration for the lead frame 116, the V-shaped concavity 140 may instead be positioned along the peripheral package sidewall closer to one or the other of the opposite peripheral package sidewalls 132a and 132b.

In an embodiment, the integrated circuit device 110 may instead comprise a single integrated circuit chip that is mounted to a single die pad of the lead frame 116 and electrically connected to the first set of leads 122a-122n and second set of leads 124a-124p.

While the invention has been illustrated and described in detail in the drawings and foregoing description, such illustration and description are considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims.

What is claimed is:

1. An integrated circuit device, comprising:
a package that encapsulates a lead frame and at least one integrated circuit chip, wherein the at least one integrated circuit chip is mounted to a die pad of the lead frame, said lead frame further including a plurality of leads;
wherein the package has, in top view, a square or rectangular perimeter defined by first, second, third and fourth sidewalls;
wherein first and second sidewalls are opposite each other;
wherein third and fourth sidewalls are opposite each other;
wherein a first set of the plurality of leads extend along the first sidewall and a second set of the plurality of leads extend along the second sidewall; and
wherein at least one of the third and fourth sidewalls includes a V-shaped concavity.

2. The integrated circuit device of claim 1, wherein each of the third and fourth sidewalls includes said V-shaped concavity.

3. The integrated circuit device of claim 1, wherein said at least one of the third and fourth sidewalls comprises:
a first sidewall portion;
a second sidewall portion joined to the first sidewall portion at a first outside corner;
a third sidewall portion joined to the second sidewall portion at an inside corner; and
a fourth sidewall portion joined to the third sidewall portion at a second outside corner.

4. The integrated circuit device of claim 3, wherein the second sidewall portion and the third sidewall portion define the V-shaped concavity.

5. The integrated circuit device of claim 3, wherein the first outside corner is defined by an outside angle α between the first sidewall portion and the second sidewall portion, and wherein the second outside corner is defined by the outside angle α between the third sidewall portion and the fourth sidewall portion.

6. The integrated circuit device of claim 5, wherein the outside angle α sets a width of the V-shaped concavity.

7. The integrated circuit device of claim 5, wherein the outside angle α sets a depth of the V-shaped concavity.

8. The integrated circuit device of claim 3, wherein the inside corner is defined by an inside angle β between the second sidewall portion and the third sidewall portion.

9. The integrated circuit device of claim 8, wherein the outside angle α sets a width of the V-shaped concavity.

10. The integrated circuit device of claim 8, wherein the outside angle α sets a depth of the V-shaped concavity.

11. The integrated circuit device of claim 3, wherein first sidewall portion extends perpendicularly from the first sidewall, and the fourth sidewall portion extends perpendicularly from the second sidewall.

12. The integrated circuit device of claim 3, wherein the V-shaped concavity has a width between the first and second outside corners that is between 0.35*L and 0.55*L, where L is a length of the third or fourth sidewall.

13. The integrated circuit device of claim 3, wherein the V-shaped concavity has a depth from a plane of the third or fourth sidewall that is between 0.15*L and 0.30*L, where L is a length of the third or fourth sidewall.

14. The integrated circuit device of claim 1, wherein the package has a thickness, and wherein the V-shaped concavity extends completely through said thickness.

15. An integrated circuit device, comprising:
a package that encapsulates a lead frame, a first integrated circuit chip and a second integrated circuit chip, wherein the first integrated circuit chip is mounted to a first die pad of the lead frame and electrically connected to a first plurality of leads of the lead frame, wherein the second integrated circuit chip is mounted to a second die pad of the lead frame and electrically connected to a second plurality of leads of the lead frame;
wherein the package has, in top view, a square or rectangular perimeter defined by first, second, third and fourth sidewalls;
wherein first and second sidewalls are opposite each other;
wherein third and fourth sidewalls are opposite each other;
wherein the first plurality of leads extend along the first sidewall and the second plurality of leads extend along the second sidewall; and
wherein at least one of the third and fourth sidewalls includes a V-shaped concavity.

16. The integrated circuit device of claim 15, wherein the first and second integrated circuit chips are electrically connected to each other.

17. The integrated circuit device of claim 16, wherein the first integrated circuit chip is a power chip and the second integrated circuit chip is a control chip configured to control operation of the power chip.

18. The integrated circuit device of claim 15, wherein each of the third and fourth sidewalls includes said V-shaped concavity.

19. The integrated circuit device of claim 15, wherein said at least one of the third and fourth sidewalls comprises:
a first sidewall portion;
a second sidewall portion joined to the first sidewall portion at a first outside corner;
a third sidewall portion joined to the second sidewall portion at an inside corner; and
a fourth sidewall portion joined to the third sidewall portion at a second outside corner.

20. The integrated circuit device of claim 19, wherein the second sidewall portion and the third sidewall portion define the V-shaped concavity.

21. The integrated circuit device of claim 19, wherein the first outside corner 150 is defined by an outside angle α between the first sidewall portion and the second sidewall portion, and wherein the second outside corner is defined by the outside angle α between the third sidewall portion and the fourth sidewall portion.

22. The integrated circuit device of claim 19, wherein the inside corner is defined by an inside angle β between the second sidewall portion and the third sidewall portion.

23. The integrated circuit device of claim 19, wherein first sidewall portion extends perpendicularly from the first sidewall, and the fourth sidewall portion extends perpendicularly from the second sidewall.

24. The integrated circuit device of claim 19, wherein the V-shaped concavity has a width between the first and second outside corners that is between 0.35*L and 0.55*L, where L is a length of the third or fourth sidewall.

25. The integrated circuit device of claim 19, wherein the V-shaped concavity has a depth from a plane of the third or fourth sidewall that is between 0.15*L and 0.30*L, where L is a length of the third or fourth sidewall.

26. The integrated circuit device of claim 15, wherein the package has a thickness, and wherein the V-shaped concavity extends completely through said thickness.
